(19) United States
(12) Patent Application Publication
(10) Pub. No.: US 2005/0276922 A1
(43) Pub. Date: Dec. 15, 2005

(54) Method of forming thin dielectric layers

(76) Inventors: Henry Bernhardt, Dresden (DE); Volker Hemel, Dresden (DE)

Correspondence Address: SLATER & MATSIL LLP, 17950 PRESTON ROAD, SUITE 1000, DALLAS, TX, 75252, US

(21) Appl. No.: 10/865,493

(22) Filed: Jun. 10, 2004

(51) Int. Cl. C23C 16/00

(52) U.S. Cl. 427/248.1

(57) ABSTRACT

Atomic layer deposition of very thin dielectric metal oxide layers in manufacturing of semiconductor devices by ozone oxidation of precursor monolayers leads to unacceptable impurity content and leakage current of the layers. It is proposed to perform precursor oxidation by means of radicals generated by oxidizing and reductive gases, which are simultaneously fed into the reaction vessel. This way very low impurity content and leakage current is achieved even in very thin (several nm) layers.

### TECHNICAL FIELD

The present invention relates to a method of forming dielectric layers, particularly in the field of integrated semiconductor devices such as DRAM. More particularly it relates to a method of forming layers of metal oxides such as aluminium or hafnium oxide by atomic layer deposition (ALD).

### BACKGROUND

The method of chemical vapor deposition (CVD) is well known in the technology of semiconductor devices as a powerful tool to generate thin layers of various chemical nature. ALD is a specific CVD method that was developed to generate layers of uniform thickness independent on the topography of the substrate. In this method, a precursor compound for the desired layer material is adsorbed on the substrate in a monomolecular layer. Excess precursor is removed in a subsequent purging step. In a third step the substrate is exposed to a reactive chemical which converts the monolayer of precursor molecules into the desired material by chemical reaction. By-products of the reaction and excess precursor are then removed in another purging step. This sequence is repeated until the desired layer thickness is achieved. In this way, it is possible to generate layers of uniform thickness even on substrates having a topography with high aspect ratio such as deep trenches.

Dielectric layers as necessary for integrated capacitors often consist of metal oxides such as aluminum, hafnium or silicium oxides. In the ALD method, a compound of the metal component is used to generate the monolayers and an oxidizing agent is utilized to convert this compound into metal oxide. A useful oxidizing agent is ozone. Generally, the ozone is applied under a pressure of more than 130 Pa. It has, however, been observed that the resulting metal oxide layer contains some impurities such as carbon and hydrogen. These impurities are not removed completely during ozone oxidation of the metallo-organic precursor molecules. Impurities give rise to undesired leakage currents in the dielectric layer forming part of a capacitor. The problem aggravates as the thickness of the dielectric layer is reduced in order to obtain a higher ratio of capacitance to volume.

U.S. Pat. No. 6,200,893 B1, which is incorporated herein by reference, gives some background to the ALD method and describes the use of radical oxygen generated by a separate plasma device as an oxidizing agent in one of a plurality of steps.

U.S. 2003/0232511 A1, which is incorporated herein by reference, discloses a method of forming a film on a substrate comprising deposition of a precursor containing a metal and then reacting it with oxygen radicals formed in a remote plasma source.

U.S. Pat. No. 6,599,842 B2, which is incorporated herein by reference, discloses a method for generation of a silicon oxide layer on a silicon workpiece such as a semiconductor wafer. The workpiece is heated to a predetermined temperature in a vessel and an oxidative and a reductive gas are supplied into the vessel, thereby producing active hydroxyl and active oxygen species such as radicals. Pressure in the vessel must be reduced in order to extend the life of the active species so that they can react with the surface of the workpiece and not with themselves causing strong exothermic reaction or even detonation.

### SUMMARY OF THE INVENTION

In one aspect, the present invention provides a method for formation of thin dielectric layers in semiconductor devices by atomic layer deposition which yields layers having few impurities and which is simpler than prior art methods.

The preferred embodiment provides a method of forming a thin dielectric layer of an oxide of a metal on a substrate residing in a processing vessel. In this method, the surface of the substrate is exposed to a precursor compound of the metal in gaseous form. Molecules of the precursor are allowed to adsorb on the surface. The surface is then exposed to a first inert purging gas, thereby removing from the surface the molecules of the precursor, which are in excess of a monomolecular layer. The surface is also exposed to radicals containing oxygen, thereby converting the metal compound precursor into metal oxide. The surface is then exposed to a second purging gas, thereby removing any oxidation products except for the metal oxide from the surface. These steps can be repeated until the desired thickness of the metal oxide is achieved. In the preferred embodiment, when exposing the surface to radicals containing oxygen, an oxidizing gas containing O₂, N₂O, NO, and/or NO₂, and a reductive gas containing H₂, NH₃, and/or CH₄, are supplied simultaneously by separate supply systems into the processing vessel and the pressure in the vessel is being kept low enough to avoid rapid reaction of the oxidizing and reductive gases.

It was surprisingly found that in an ALD method dielectric layers with reduced leakage current compared to prior art layers could be generated by supplying an oxidizing gas containing O₂, N₂O, NO, and/or NO₂, and a reductive gas containing H₂, NH₃, and/or CH₄, simultaneously by separate supply systems into the processing vessel after covering the surface of the substrate with a precursor monolayer. The pressure in the vessel can be kept low enough to avoid rapid reaction of the gases with one another or even detonation.

Without being bound by theory, it is believed that the advantages of the present invention are at least partly due to the fact that the oxygen containing active species or radicals thereof are a more aggressive oxidizing agent than the ozone used in prior art. Thus the ligands in the precursor molecule can be completely oxidized while leaving much less carbon or hydrogen residues in the oxide layer.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

Preferred active species/radicals containing oxygen are oxygen radicals and hydroxyl radicals. These radicals can be preferably generated by using oxygen as the oxidizing gas and hydrogen as the reductive gas. In this case, it is preferred that the molar ratio of hydrogen to oxygen is 2 or less. Particularly preferred is a molar ratio in the range of 0.1 to 1.

In a preferred embodiment of the present invention, the metal is aluminum, so that the dielectric layer resulting from the process is an aluminum oxide layer. Any suitable aluminum compound may be used as precursor with special preference to aluminum trimethyl, Al(CH₃)₃. Other organic aluminum compounds like aluminum triethyl, tri-isobutyl, tripropyl, are also useful as long as they can be brought to a gaseous state.

Another preferred metal for generating dielectric metal oxide layers according to the invention is hafnium. Useful hafnium precursors include hafnium tetrachloride, HfCl₄, tetrakis(diethylamido)hafnium (TDEAH), Hf(N(C₂H₅)₂)₄, tetrakis(methylethylamido)hafnium (TEMAH), Hf(N(CH₃C₂H₅)₂)₄, tetrakis(dimethylamido)hafnium (TDMAH), Hf(N(CH₃)₂)₄, tetrakis(t-butoxy)hafnium, Hf(t-C₄H₉O)₄, and tetrakis(ethoxy)hafnium, Hf(C₂H₅O)₄.

Other metals useful for generating dielectric metal oxide films in accordance with the present invention include, but are not limited to, tantalum, titanium, niobium, zirconium, molybdenum, indium, tin, tungsten, silicium, and the rare earth metals scandium, yttrium, cerium, praseodymium, neodymium, samarium, europium, gadolinium, terbium, dysprosium, holmium, erbium, thulium, ytterbium, and lutetium. Any inorganic or metal-organic compound containing one of these metals and capable of accepting a gaseous state is useful for performing the method of the invention. Preferred ligands (groups bound to the metal atom) to such compounds are fluorine, chlorine, bromine, iodine, and alkyl such as methyl or ethyl as well as alkyloxy and dialkylamino such as methoxy, ethoxy, and dimethylamino.

The preferred embodiment provides a method of forming a thin dielectric layer of an oxide of a metal on a substrate residing in a processing vessel. In this method, the surface of the substrate is exposed to a precursor compound of the metal in gaseous form. Molecules of the precursor are allowed to adsorb on the surface. The surface is then exposed to a first inert purging gas, thereby removing from the surface the molecules of the precursor, which are in excess of a monomolecular layer. The surface is also exposed to radicals containing oxygen, thereby converting the metal compound precursor into metal oxide. The surface is then exposed to a second purging gas, thereby removing any oxidation products except for the metal oxide from the surface. These steps can be repeated until the desired thickness of the metal oxide is achieved. In the preferred embodiment, when exposing the surface to radicals containing oxygen, an oxidizing gas containing O₂, N₂O, NO, and/or NO₂, and a reductive gas containing H₂, NH₃, and/or CH₄, are supplied simultaneously by separate supply systems into the processing vessel and the pressure in the vessel is being kept low enough to avoid rapid reaction of the oxidizing and reductive gases.

As already mentioned, the pressure in the processing vessel during the exposure of the surface to radicals containing oxygen should be kept low enough to avoid a rapid reaction of the oxidizing and the reductive gas with one another. Under normal atmospheric pressure a mixture of, e.g., oxygen and hydrogen, is detonating if heated to about 600° C. or in presence of a catalyst. This is due to a chain reaction that involves oxygen and hydrogen molecules and radicals as well as hydroxyl radicals and leads eventually to water. The reaction proceeds through collision of a molecule and a radical. At sufficiently reduced pressure the chance for a radical to hit the substrate is larger than the chance to collide with a molecule. Thus, most of the radicals originally created involve themselves in oxidation of the precursor on the substrate.

A preferred range for the pressure during the above-reference exposure step is from 13 to 260 Pa, with particular preference for 39 to 130 Pa.

Preferably there are no significant amounts of other gases (like inert gases or nitrogen) than the oxidizing and the reductive gas present during the above-referenced exposure step.

The pressure during the individual process steps is generally the same for each step. Depending on the nature of the precursors, purging gases and oxidizing and reductive gases, it may be advantageous to use different pressures for one or more steps.

The temperature during the oxygen exposure step is maintained high enough for generation of radicals in the mixture of the oxidizing and the reductive gas, but not so high that complete combustion takes place. It depends to a certain extent on the nature of the gases and the precursor. Generally it has been shown that a useful range is between 200 and 550° C., but these limits may be exceeded. A preferred range is from 250 to 500° C. with particular preference for 300 to 400° C.

A particularly useful embodiment of the invention is directed to a method of forming a dielectric layer of aluminum oxide on a substrate. This embodiment comprises the steps of
a) exposing the surface of the substrate to a precursor compound of aluminum in gaseous form and allowing molecules of the precursor to adsorb on the surface,
b) exposing the surface to a first inert purging gas, thereby removing from the surface the molecules of the precursor which are in excess of a monomolecular layer,
c) exposing the surface to radicals containing oxygen, thereby converting the aluminum compound precursor into aluminum oxide,
d) exposing the surface to a second purging gas, thereby removing any oxidation products except for the aluminum oxide from the surface,
e) repeating steps a) through d) until the desired thickness of the aluminum oxide is achieved. In performing step c) oxygen and hydrogen are supplied simultaneously by separate supply systems into the processing vessel and the pressure in the vessel is low enough to avoid detonation of the oxidizing and reductive gases.

The molar ratio of hydrogen to oxygen in step c) is preferably 2 or less with particular preference to 0.1 to 1.

The pressure during step c) is preferably from 13 to 2000 Pa with particular preference for 39 to 130 Pa.

A preferred range of temperature in step c) is between 300 and 400° C.

The number of repetitions of steps a) through d) depends on the nature of the metal oxide forming the dielectric layer and on the desired thickness of the layer. It has been found that a 4 nm layer of aluminum oxide can be formed with between 50 and 100 repetitions, e.g., about 60 repetitions.

The method according to the present invention can be performed in any useful device or equipment known in the art for growing layers on semiconductor substrates. Examples of such equipment can be found in the references cited above.

Before applying a substrate to the method of the present invention for growing dielectric metal oxide layers, it is possible to apply one of the pre-treatment methods known in the art.

The dielectric metal oxide layers grown with the method according to the present invention show a significantly lower leakage current than layers generated with prior art methods. Furthermore the method of the present invention is simpler than prior art methods in that it does not require any separate or remote plasma device for generating radicals and also no carrier gases.

The method according to the present invention can be applied to any dielectric metal oxide layer needed in highly integrated semiconductor devices, in particular for topography with high aspect ratio such as deep trenches for capacitors.

Although the present invention and its advantages have been described in detail, it should be understood that various changes, substitutions and alterations can be made herein without departing from the spirit and scope of the invention as defined by the appended claims.

1. A method of forming a metal oxide layer on a substrate residing in a processing vessel, the method comprising:
a) exposing the surface of a substrate to a precursor compound of a metal in gaseous form and allowing molecules of said precursor to adsorb on said surface;
b) exposing said surface to a first inert purging gas, thereby removing from said surface molecules of said precursor;
c) exposing said surface to radicals containing oxygen, thereby converting said metal compound precursor into metal oxide, wherein an oxidizing gas containing O₂, N₂O, NO, and/or NO₂, and a reductive gas containing H₂, NH₃, and/or CH₄, are supplied simultaneously by separate supply systems into said processing vessel and the pressure in the vessel is being kept low enough to avoid rapid reaction of said oxidizing and reductive gases;
d) exposing said surface to a second purging gas, thereby removing oxidation products other than the metal oxide from said surface; and
e) repeating steps a) through d) until the desired thickness of the metal oxide is achieved.

2. The method of claim 1, wherein the radicals containing oxygen are oxygen or hydroxyl radicals.

3. The method of claim 1, wherein the oxidizing gas is oxygen.

4. The method of claim 1, wherein the reductive gas is hydrogen.

5. The method of claim 1, wherein the exposing of step b) removes from said surface any molecules of said precursor, which are in excess of a monomolecular layer.

6. The method of claim 4, wherein the molar ratio of hydrogen to oxygen is 2 or less.

7. The method of claim 6, wherein the molar ratio of hydrogen to oxygen is in the range from 0.1 to 1.

8. The method of claim 1, wherein the metal is aluminum.

9. The method of claim 8, wherein the precursor is aluminum trimethyl or triethyl.

10. The method of claim 1, wherein the metal is hafnium.

11. The method of claim 10, wherein the precursor comprises a material selected from the group consisting of hafnium tetrachloride, tetrakis(diethylamido)hafnium, tetrakis(methylethylamido)hafnium, tetrakis(dimethylamido)hafnium, tetrakis(t-butoxy)hafnium, and tetrakis(ethoxy)hafnium and combinations thereof.

12. The method of claim 1, wherein the metal comprises at least one metal selected from the group consisting of tantalum, titanium, niobium, zirconium, molybdenum, indium, tin, tungsten, silicium, and the rare earth metals.

13. The method of claim 1, wherein the pressure during step c) is in the range from 13 to 260 Pa.

14. The method of claim 13, wherein the pressure during step c) is in the range from 39 to 130 Pa.

15. The method of claim 1, wherein the temperature during step c) is in the range from 250 to 500° C.

16. The method of claim 15, wherein the temperature during step c) is in the range from 300 to 400° C.

17. The method of claim 15, wherein the temperature during step c) is in the range from 350 to 400° C.

18. A method of forming a layer of aluminum oxide on a substrate residing in a processing vessel, the method comprising:
a) exposing the surface of the substrate to a precursor compound of aluminum in gaseous form and allowing molecules of said precursor to adsorb on said surface;
b) exposing said surface to a first inert purging gas, thereby removing from said surface molecules of said precursor;
c) exposing said surface to radicals containing oxygen, thereby converting said aluminum compound precursor into aluminum oxide, wherein oxygen and hydrogen are supplied simultaneously by separate supply systems into said processing vessel and the pressure in the vessel is low enough to avoid detonation of said oxidizing and reductive gases;
d) exposing said surface to a second purging gas, thereby removing oxidation products from said surface; and
e) repeating steps a) through d) until a desired thickness of the aluminum oxide is achieved.

19. The method of claim 18, wherein the molar ratio of hydrogen to oxygen is 2 or less.

20. The method of claim 18, wherein the exposing of step b) removes from said surface any molecules of said precursor, which are in excess of a monomolecular layer.

21. The method of claim 19, wherein the molar ratio of hydrogen to oxygen is in the range from 0.1 to 1.

22. The method of claim 18, wherein the pressure during step c) is in the range from 13 to 260 Pa.

23. The method of claim 22, wherein the pressure during step c) is in the range from 39 to 130 Pa.

24. The method of claim 18, wherein the temperature during step c) is in the range from 300 to 400° C.
